(19) United States
(12) Patent Application Publication
(10) Pub. No.: US 2010/0186802 A1
(43) Pub. Date: Jul. 29, 2010

(54) HIT SOLAR CELL STRUCTURE

(76) Inventor: Peter BORDEN, San Mateo, CA (US)

Correspondence Address: APPLIED MATERIALS;C/O PILLSBURY WINTHROP SHAW PITTMAN LLP, P .O . BOX 10500, MCLEAN, VA, 22120, US

(21) Appl. No.: 12/360,797

(22) Filed: Jan. 27, 2009

(51) Int. Cl. H01L 31/00; H01L 31/0376

(52) U.S. Cl. 136/255; 136/258; 438/87; 257/E31.048

(57) ABSTRACT

The present invention relates to improved HIT type or polysilicon emitter solar cells. According to certain aspects, the invention includes forming a masking oxide layer on the front and back of the cell and then patterning holes in the masking oxide. A HIT cell structure or polysilicon emitter solar cell structure is then formed over the patterned oxide, creating the cell junction only in the areas where holes have been cut. Benefits of the invention include that it provides a controlled interface for the HIT cell through insertion of a thin tunnel oxide. Moreover, the tunnel oxide prevents epitaxial growth of amorphous silicon, allowing it to remain amorphous for the optimum band structure. Still further, it provides a layer to protect the surface from plasma damage during deposition of the a-Si layer. Further, it may be used in conjunction with a point contact structure to further increase efficiency.

### CROSS-REFERENCE TO RELATED APPLICATIONS

### FIELD OF THE INVENTION

The present invention relates to photovoltaic devices, and more particularly to methods and apparatuses for providing an improved structure of a HIT type or polysilicon emitter type solar cells.

### BACKGROUND

HIT type solar cells are high efficiency devices with relatively simple structures. Sanyo Corporation of Japan has reported lab efficiencies of 21.5% and manufacturing efficiency in the mid-19% range. Many other groups have worked on this device, although none has shown as high efficiencies.

A typical HIT type solar cell structure is shown in FIGS. 1A and 1B. The device is symmetric, with the front and back of the n-type substrate 106 both coated with a coating 102 and 110, respectively and metal grid lines 104 and 108, respectively. As shown in the blowup portion of FIG. 1B, the coating 102 on the front consists of two amorphous silicon layers, an intrinsic layer 126 under a p-type layer 124, both about 50 Angstroms thick. On the back, the amorphous silicon layer consists of an intrinsic (i) layer under an n-type layer. As further shown in FIG. 1B, the coating 102 further includes a layer of transparent conductive oxide (TCO) 122.

The purpose of the thin a-Si layers is to both passivate the surface and to provide a heterojunction with a wide bandgap window layer to improve the open circuit voltage, as shown in FIG. 1C. More particularly, FIG. 1C illustrates the band structure of such a device. As shown in FIG. 1C, there is a large potential step at the front surface, creating a junction much like a junction found at the step between p- and n-type dopants. However, because this junction is formed by depositing a layer of amorphous silicon, it is very abrupt, and nearly ideal.

Despite their benefits, these amorphous silicon layers also introduce considerable complexity into the fabrication of the HIT cell. For example, the layers must be formed on a carefully prepared surface, whose preparation details have not been published. Further, they must not crystallize, as can happen when the amorphous silicon is seeded by the crystal silicon substrate, as this will eliminate the beneficial passivation and heterojunction effects.

Therefore, there is a lingering need for an improved interface that is well controlled and understood and easy to manufacture, and does not seed crystal growth.

### SUMMARY

The present invention relates to improved HIT type or polysilicon emitter solar cells. According to certain aspects, the invention includes forming a masking oxide layer on the front and back of the cell and then patterning holes in the masking oxide. A HIT cell structure or polysilicon emitter solar cell structure is then formed over the patterned oxide, creating the cell junction only in the areas where holes have been cut. Benefits of the invention include that it provides a controlled interface for the HIT cell through insertion of a thin tunnel oxide. Moreover, the tunnel oxide prevents epitaxial growth of amorphous silicon, allowing it to remain amorphous for the optimum band structure. Still further, it provides a layer to protect the surface from plasma damage during deposition of the a-Si layer. Further, it may be used in conjunction with a point contact structure to further increase efficiency.

In furtherance of these and other aspects, a solar cell according to embodiments of the invention comprises an amorphous semiconductor layer formed over a substrate; and a dielectric layer interposed between the substrate and the amorphous semiconductor layer, wherein the dielectric layer is sufficiently thin so as to support a tunneling current therethrough.

In additional furtherance of these and other aspects, a method of fabricating a solar cell according to embodiments of the invention includes forming a dielectric layer on a substrate, wherein the dielectric layer is sufficiently thin so as to support a tunneling current therethrough; and forming an amorphous semiconductor layer formed over the dielectric layer.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIGS. 1A to 1C show a conventional HIT cell and its band structure.

FIGS. 2A and 2B show an example solar structure of the present invention and its band structure, respectively.

FIG. 3 is a diagram illustrating an example process flow to form the structure of FIG. 2 according to aspects of the invention.

### DETAILED DESCRIPTION

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

In general, the present inventors recognize that thin tunnel oxide layers can be used in solar cells. For example, some MIS cells can be made using aluminum over tunnel oxides. The present inventors further recognize that tunnel oxides can be used between a heavily doped or insulating layer of polysilicon and a crystal silicon substrate, forming a polysilicon emitter solar cell. Such a solar cell has a similar band structure to a HIT cell, essentially replacing the TCO and a-Si layers with polysilicon. However, such cells do not provide the heterojunction and its benefit of a higher cell voltage due to the higher bandgap of a-Si.

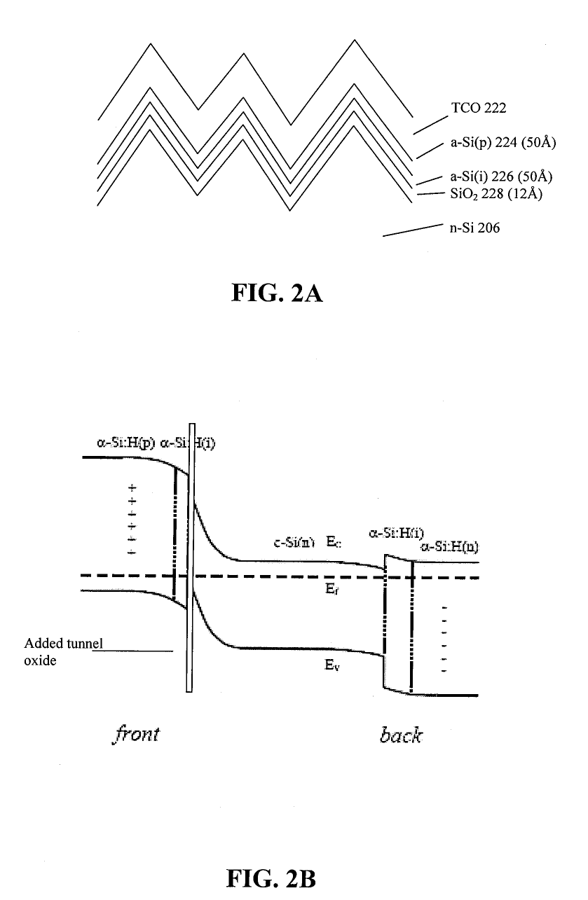

An example solar cell structure according to embodiments of the invention and the associated band structure is shown in FIGS. 2A and 2B, respectively.

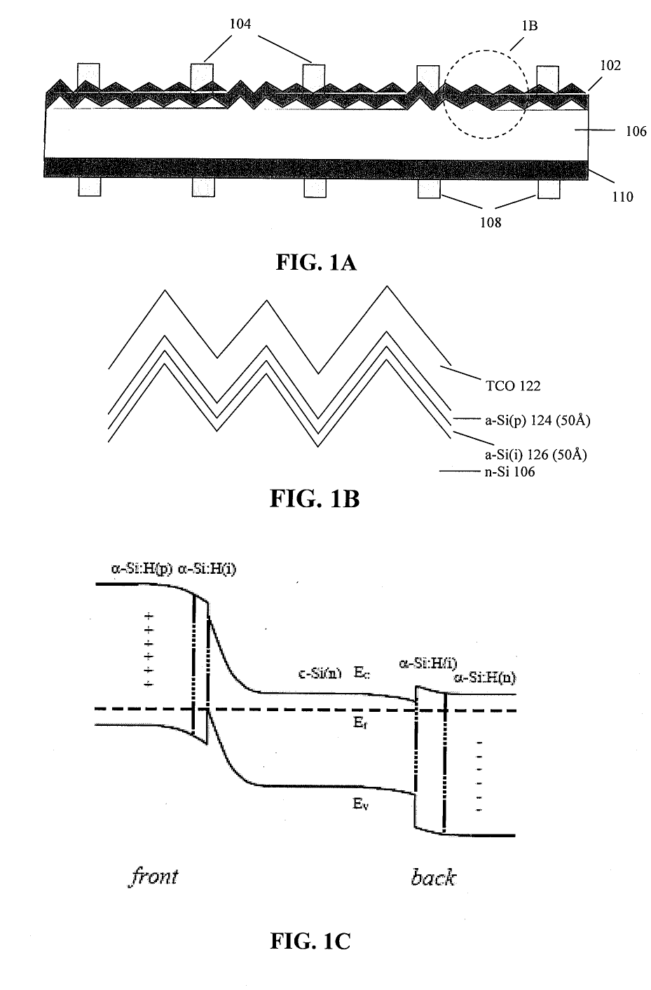

As shown in FIG. 2A, which can be part of a front surface of a HIT-type solar cell similar to that shown in FIG. 1, a thin dielectric layer 228 (e.g. tunnel oxide) is provided between the a-Si layers 224 and 226 and the n-type substrate 206 in a HIT cell. The dielectric layer is preferably thin, on the order of 8-15 Å, in order to support a tunneling current between the substrate and a-Si layers. As will be described in more detail below, layer 228 can be formed using conventional methods such as rapid thermal oxidation, furnace oxidation, or the Chemox process (formation in an ozonated H₂O₂ bath). In some cases, the layer may be nitrided or formed using other materials such as silicon nitride or silicon oxynitride.

As shown in FIG. 2B, added dielectric layer at the interface provides a bandgap much larger than the bandgap of the semiconductors. Carriers cannot get over the energy barrier, but tunnel through if the layer is sufficiently thin (<15 Å). Note that oxide and nitride will have different barrier heights, so the layer shown is not meant to represent any one material. The barrier height for nitride is about 2.5 eV and is symmetric. The barrier height for oxide is asymmetric (lower for electrons).

The benefits provided by dielectric layer 228 are several-fold. For example, it may be formed using conventional surface cleaning and preparation methods, as are used to make MOS gates for ICs. Therefore, the surface preparation is well known and understood, and routinely implemented in high volume manufacturing. Moreover, as it is an amorphous layer, it separates the subsequent a-Si layer from the substrate, preventing epitaxial seeding of crystal growth in the a-Si layer. Further, it provides an intervening layer to protect the crystal silicon surface from plasma damage during deposition of the a-Si layer.

It should be noted that, although benefits of the invention are obtained with a-Si layers formed over a crystalline silicon substrate, that this is not limiting, and that the invention can be applied to other types of substrates and thin semiconductor layers. It should be further noted that many solar cells use heterojunctions. So, for example, the invention could be used with a thin film solar cell with amorphous silicon on micro-crystal silicon. It could also be used on CdTe, CIGS or AlGaAs/GaAs cells, all of which use heterojunctions.

That said, it should be still further noted that amorphous silicon on silicon is known to provide excellent passivation properties, nearly eliminating surface recombination. This is because the high band bending at the surface repels carriers. Accordingly, this is one advantage of using amorphous silicon on silicon.

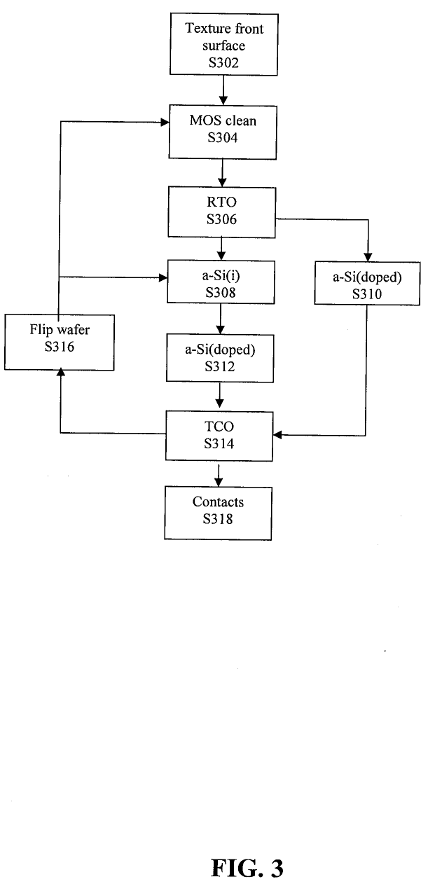

FIG. 3 is a diagram illustrating an example process flow used to make the structure of FIG. 2A. First, in step S302, the front surface of the n-type substrate is textured. This may be accomplished using conventional etching, such as isopropyl alcohol and KOH. Next in step S304, the surface is provided with a standard MOS clean to remove native oxides, ionic contamination, and organics.

In one embodiment, a rapid thermal oxide process is then used in step S306 to form a thin tunnel oxide, typically 12 Å thick, on the front surface. In another embodiment of the invention, the oxide is formed on both front and back at the same time. Next the a-Si layers are deposited on the front surface. In one embodiment, the a-Si is formed as a two layer stack on the front surface, with an intrinsic a-Si, 20-50 Å thick formed first in step S308, for example by plasma enhanced chemical vapor deposition (PE-CVD), which is the decomposition of silane in a plasma, often with hydrogen present. These processes are well known in the literature. Boron may be added to provide p-type doping, and phosphorous may be added to provide n-type doping. Next, a p-type a-Si, 20-50 Å thick is formed on top of the intrinsic a-Si layer in step S312, for example by the same PE-CVD process. In another embodiment, only a doped p-type layer is formed on the front surface in step S310, without the i-type layer. The TCO is deposited in step S314, which may be a quarter wave thick layer of indium tin oxide.

The wafer is then flipped over in step S316, and the structure is deposited in the same manner on the back side, now using n-type a-Si instead of p-type. As shown, depending on whether the oxide layer has already been formed, processing returns to step S306 or step S308. It should be further apparent that processing could also return to step S310 if the oxide layer has already been formed. Finally, contacts are formed in step S318, for example by screen printing or sputtering.

Additionally or alternatively to the process described above, a method to form point contacts for HIT or polysilicon emitter solar cells, as described in co-pending application No. ______ (AMAT-12964), the contents of which are incorporated herein by reference in their entirety, may be performed.

Although the present invention has been particularly described with reference to the preferred embodiments thereof, it should be readily apparent to those of ordinary skill in the art that changes and modifications in the form and details may be made without departing from the spirit and scope of the invention. It is intended that the appended claims encompass such changes and modifications.

What is claimed is:

1. A solar cell comprising:
an amorphous semiconductor layer formed over a substrate;
a dielectric layer interposed between the substrate and the amorphous semiconductor layer, wherein the dielectric layer is sufficiently thin so as to support a tunneling current therethrough.

2. A solar cell according to claim 1, wherein the substrate comprises silicon and the dielectric layer comprises silicon dioxide.

3. A solar cell according to claim 1, wherein the substrate comprises silicon and the dielectric layer comprises nitrogen.

4. A solar cell according to claim 1, wherein the amorphous semiconductor layer comprises silicon.

5. A solar cell according to claim 1, wherein the amorphous semiconductor layer comprises a two-layer stack of an intrinsic amorphous silicon layer and a doped amorphous silicon layer.

6. A solar cell according to claim 1, wherein the amorphous semiconductor layer is formed on a front surface of the substrate, wherein the solar cell further comprises:
another amorphous semiconductor layer is formed on an opposite back surface of the substrate; and
another dielectric layer interposed between the substrate and the another amorphous semiconductor layer, wherein the another dielectric layer is sufficiently thin so as to support a tunneling current therethrough.

7. A solar cell according to claim 6, wherein both the amorphous semiconductor layer and the another amorphous semiconductor layer comprise a two-layer stack of an intrinsic amorphous silicon layer and a doped amorphous silicon layer.

8. A method of fabricating a solar cell, comprising:
forming a dielectric layer on a substrate, wherein the dielectric layer is sufficiently thin so as to support a tunneling current therethrough; and
forming an amorphous semiconductor layer formed over the dielectric layer.

9. A method according to claim 8, wherein the step of forming the amorphous semiconductor layer includes forming a two-layer stack of an intrinsic amorphous silicon layer and a doped amorphous silicon layer.

10. A method according to claim 8, further comprising:
texturing a surface of the substrate before forming the dielectric layer.

11. A method according to claim 8, wherein a rapid thermal oxide process is used to form the dielectric layer.

12. A method according to claim 9, wherein the intrinsic and doped amorphous silicon layers are both about 20-50 Å thick.

13. A method according to claim 8, further comprising depositing a layer of TCO over the amorphous semiconductor layer.

14. A method according to claim 13, wherein the TCO comprises a quarter wave thick layer of indium tin oxide.

15. A method according to claim 8, wherein the amorphous semiconductor layer is formed on a front surface of the substrate, wherein the method further comprises:
forming another dielectric layer on an opposite back surface of the substrate, wherein the another dielectric layer is sufficiently thin so as to support a tunneling current therethrough; and
forming another amorphous semiconductor layer over the another dielectric layer.
